(19) United States
(12) Patent Application Publication
(10) Pub. No.: US 2009/0072402 A1
(43) Pub. Date: Mar. 19, 2009

(54) SEMICONDUCTOR DEVICE AND METHOD OF FABRICATING THE SAME

(75) Inventor: Young Geun Jang, Seoul (KR)

Correspondence Address: MARSHALL, GERSTEIN & BORUN LLP, 233 SOUTH WACKER DRIVE, 6300 SEARS TOWER, CHICAGO, IL, 60606-6357, US

(73) Assignee: HYNIX SEMICONDUCTOR INC., Icheon-Si (KR)

(21) Appl. No.: 11/950,498

(22) Filed: Dec. 5, 2007

(30) Foreign Application Priority Data
Sep. 17, 2007 (KR) 2007-0094131

(51) Int. Cl. H01L 23/52; H01L 21/4763

(52) U.S. Cl. 257/751; 438/669; 257/E21.495; 257/E23.141

(57) ABSTRACT

A method of fabricating a semiconductor device comprising forming a metal layer on a semiconductor substrate, patterning the metal layer to form a plurality of metal wires having side surfaces, forming spacers on both side surfaces of each of the metal wires, and forming an insulating layer between the spacers of the adjacent metal wires, the insulating layer having voids formed therein and being formed with material having a dielectric constant which differs from that of the spacers, and a semiconductor device made by this method.

### CROSS-REFERENCE TO RELATED APPLICATION

The priority of Korean Patent Application No. 2007-0094131, filed on Sep. 17, 2007, the disclosure of which is incorporated herein by reference in its entirety, is claimed.

### BACKGROUND OF THE INVENTION

The invention relates to a semiconductor device and a method of fabricating the same and, more particularly, relates to a semiconductor device which can achieve a low dielectric ratio between metal wires and maintain excellent electrical characteristics and mechanical strength, and a method of fabricating the same.

A metal wiring process is a process for electrically connecting the circuits formed on a semiconductor substrate to each other through metal wires. The metal wire is generally formed with metal material such as aluminum (Al), copper (Cu), gold (Au) or tungsten (W). In general, the metal wiring process is performed by a damascene method comprising the steps of forming a metal layer on an interlayer insulating layer and then patterning the metal layer, depositing insulating material between the metal wires or forming a trench in the interlayer insulating layer, and filling the trench with metal material and planarizing the trench.

As semiconductor devices have become more highly-integrated, the spaces between the metal wires have been reduced in size. In a case where the interlayer insulating layer is formed with material having a high dielectric constant such as silicon oxide (SiO₂; ε=3.9), signal transmission is delayed due to increases of the parasitic capacitance between the metal wires and electrical interference between the metal wires.

To reduce the parasitic capacitance between the metal wires causing the above problem, efforts lower resistance of material used for forming the metal wire or the dielectric ratio of insulating material to be deposited between the metal wires have been made.

In an effort to solve this problem, a method in which low dielectric material is used for forming the interlayer insulating layer has been introduced. However, since low dielectric material has inferior electrical characteristics and low mechanical strength, this method has the disadvantages that low dielectric material does not generally withstand the mechanical effects during a subsequent chemical mechanical polishing process and the reliability of the semiconductor device is lowered due to this drawback.

### SUMMARY OF THE INVENTION

The invention provides a semiconductor device having spacers formed on both side walls of metal wires to reduce a gap therebetween and an insulating layer formed between the spacers and having artificially formed voids, and a method of fabricating the same. The invention can achieve a low dielectric ratio between the metal wires to improve a resistance-capacitance (RC) delay characteristic and maintain a mechanical strength during a subsequent chemical mechanical polishing process.

The method of fabricating a semiconductor device according to one embodiment of the invention comprises forming a metal layer on a semiconductor substrate; patterning the metal layer to form a plurality of metal wires; forming spacers on both side surfaces of each of the metal wires; and forming an insulating layer between the spacers of the adjacent metal wires, the insulating layer having voids formed therein and comprising material having a dielectric constant which differs from that of the spacers.

The method of fabricating a semiconductor device according to another embodiment of the invention comprises forming a metal layer on a semiconductor substrate; patterning the metal layer to form a plurality of metal wires; forming spacers on both side surfaces of each of the metal wires; and forming an insulating layer between the spacers of the adjacent metal wires, the insulating layer having voids formed therein and comprising material having a mechanical strength higher than that of low dielectric material.

In the above method, the spacer preferably comprises of a O₃-TEOS (Tetra Ethyl Ortho Silicate) layer. The O₃-TEOS layer is preferably formed through a sub-atmospheric chemical vapor deposition (SACVD) method performed in a chamber at a temperature of 500° C. to 550° C.

The spacer preferably has a thickness of 100 Å to 1,500 Å. Forming the spacer preferably comprises the steps of forming a O₃-TEOS layer on the semiconductor substrate along a plurality of metal wires; and etching the O₃-TEOS layer to form spacers on both side walls of each of the metal wires.

The insulating layer is preferably formed with material having a dielectric constant lower than that of the spacer. The insulating layer is preferably formed by a plasma enhanced chemical vapor deposition (PECVD) method and preferably comprises one of a PE-TEOS (Plasma Enhanced-Tetra Ethyl Ortho Silicate) layer, a PE-USG (Plasma Enhanced-Undoped Silicate Glass) layer, and a PE-FSG((Plasma Enhanced-Fluoro Silicate Glass) layer. The insulating layer preferably has a thickness of 1,000 Å to 13,000 Å.

A semiconductor device according to one embodiment of the invention comprises a plurality of metal wires formed on a semiconductor substrate; spacers formed on both side walls of each of the metal wires; an insulating layer formed between the spacers of the adjacent metal wires; and voids formed in the insulating layer between the metal wires.

The spacer is preferably formed of a O₃-TEOS layer. The spacer preferably has a thickness of 100 Å to 1,500 Å. The insulating layer preferably comprises material having a dielectric constant lower than that of the spacer. The insulating layer preferably comprises material having a mechanical strength higher than that of low dielectric material. The insulating layer preferably comprises of a PE-TEOS layer, a PE-USG layer, and a PE-FSG layer. Te insulating layer preferably has a thickness of 1,000 Å to 13,000 Å.

### BRIEF DESCRIPTION OF THE DRAWINGS

The foregoing and other features and advantages of the invention will become readily apparent by reference to the following detailed description when considered in conjunction with the accompanying drawings wherein:

FIG. 1A to FIG. 1E are sectional views of a semiconductor device illustrating a method of fabricating a semiconductor device according to the embodiment of the invention.

### DESCRIPTION OF SPECIFIC EMBODIMENTS

Hereinafter, preferred embodiments of the invention are explained in more detail with reference to the accompanying drawings. However, the embodiments of the invention may be modified in various ways and the scope of the invention should not be limited to the illustrated embodiments. The description herein is provided for illustrating more completely to those skilled in the art.

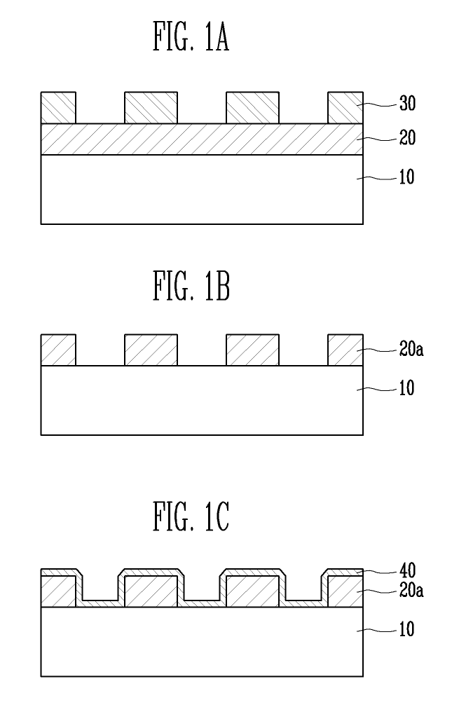

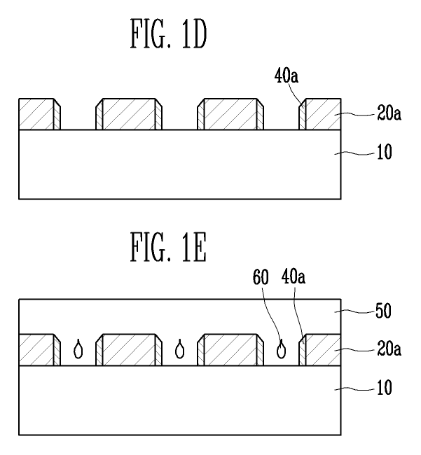

FIG. 1A to FIG. 1E are sectional views of a semiconductor device illustrating a method of fabricating a semiconductor device according to the embodiment of the invention.

Referring to FIG. 1A, metal material is deposited on a semiconductor substrate 10 on which a predetermined structure such as a gate (not shown) and an interlayer insulating layer (not shown) are formed, to form a metal layer 20. Any suitable conductive material having a low resistance may be used to form the metal layer 20. For example, the metal layer can be formed with aluminum (Al), tungsten (W), gold (Au), copper (Cu), titanium (Ti), and the like. The metal layer 20 can be formed through the physical vapor deposition (PVD) method, and it is preferable to form the metal layer through the sputtering method.

Subsequently, etching masks 30 spaced from each other at a predetermined distance are formed on the metal layer 20 to expose portions of a surface of the metal layer 20. Photoresist patterns can be utilized as the etching masks 30. In this case, photoresist is applied on the metal layer 20, and the photoresist is then patterned through an exposure process and a developing process to form the photoresist patterns.

Referring to FIG. 1B, the metal layer 20 is patterned through an etching process utilizing the etching mask 30. At this time, a dry etching process can be performed as the etching process. Preferably, a reactive ion etching (RIE) process can be carried out for patterning the metal layer. Thereby, a plurality of metal wires 20a spaced apart from each other at a predetermined distance are formed on the semiconductor substrate 10. The etching masks 30 are then removed.

Referring to FIG. 1C, a first insulating layer 40 is formed on the semiconductor substrate 10 including the metal wires 20a. The first insulating layer 40 is formed for forming spacers on side walls of the metal wires 20a, and is preferably formed of a O₃-TEOS (tetra ethyl ortho silicate) layer. The O₃-TEOS layer is preferably formed through a sub-atmospheric chemical vapor deposition (SACVD) method utilizing O₃-TEOS as the source. At the time of forming the O₃-TEOS layer, temperature in the chamber is typically maintained within a range of 500° C. to 550° C. In addition, the first insulating layer 40 preferably has a thickness of 100 Å to 1,500 Å.

In the above sub-atmospheric chemical vapor deposition process, a substance (O₃ and TEOS in this embodiment) to be reacted is introduced into a chamber and then preferably deposited by chemical vapor deposition (CVD), the thermal energy (preferably at a temperature of 500° C. to 550° C. in the invention) is used as the energy source, and pressure in the chamber is maintained within a certain range (in general, approximately 600 Torr) which is somewhat lower than a normal pressure, in order to promote a reaction.

The step coverage characteristic of a layer formed through a conventional plasma enhanced chemical vapor deposition (PECVD) method is not excellent, and so an oxide layer formed on side walls is less dense than that formed on a flat region. However, in a case where the O₃-TEOS layer is formed through a sub-atmospheric chemical vapor deposition process (SACVD) method, the O₃-TEOS layer has an extraordinarily excellent step coverage property. Like the O₃-TEOS layer formed on an upper flat portion of the metal wire 20a, the O₃-TEOS layer formed on side walls of the metal wire is more dense.

Accordingly, the spacer obtained by using the O₃-TEOS layer in the subsequent process is denser than that formed of a conventional PE-TEOS layer so that it is possible to reduce a leakage current on the side walls of the metal wire 20a.

Referring to FIG. 1D, the first insulating layer 40 is etched through a space etching process to form spacers 40a on both side surfaces of each of the metal wires 20a. At this time, a dry etching process may be performed for forming the spacer. Preferably, a blanket etching process may be performed for forming the spacer. In this case, in the etching process, horizontal portions of the first insulating layer 40 are selectively removed and vertical portions are remained, and so the spacers 40a are formed on both side walls of each metal wire 20a. Due to the above structure, a portion of the semiconductor substrate 10 between the spacers 40a is exposed. In the etching process, on the other hand, a portion of the horizontal surface of the first insulating layer 40 between the metal wires 20a on the semiconductor substrate 10 may remain.

As described above, in a case where the spacers 40a formed of the O₃-TEOS layer are formed on both side surfaces of the metal wire 20a, a gap between the metal wires 20a is narrowed. Accordingly, when an insulating layer is formed for filling a gap between the spacers 40a, voids can be artificially formed in the insulating layer between the metal wires 20a.

In addition, since the O₃-TEOS layer is more dense than a conventional PE-TEOS, it is possible to reduce a leakage current through the side walls of metal wire 20a.

Referring to FIG. 1E, a second insulating layer 50 is formed on the semiconductor substrate 10 including the metal wires 20a, each of which having the spacers 40a formed on the both side walls thereof. Here, the second insulating layer 50 is formed with material having a dielectric constant which differs from that of the spacer 40a, preferably, lower than that of the spacer 40a. In addition, the second insulating layer 50 is preferably formed with material having a mechanical strength higher than that of a low dielectric material. Preferably, the second insulating layer 50 may be formed on any of a PE-TEOS (plasma enhanced-tetra ethyl ortho silicate) layer, a plasma enhanced-undoped silicate glass (PE-USG) layer, and a plasma enhanced-fluoro silicate glass (PE-FSG) layer. At this time, the PE-TEOS layer is preferably formed through the plasma enhanced chemical vapor deposition (PECVD) method in which TEOS gas is used as the basic reaction gas. The PE-USG layer is preferably formed through the PECVD method in which silane (SiH₄) gas is utilized as the basic reaction gas. In addition, the PE-FSG layer is preferably formed through the PECVD method in which silane (SiH₄) gas and silicon tetrafluoride (SiF₄) gas are utilized as the basic reaction gas. In particular, the PE-FSG layer is preferably formed by using the silane (SiH₄) gas so that there is an advantage that the dielectric constant of the layer can be lowered to a relatively great degree. The second insulating layer 50 preferably has a thickness of 1,000 Å to 13,000 Å.

As described above, in a case where the second insulating layer 50 is formed through the PECVD method after a gap between the metal wires 20a is narrowed through the spacers 40a formed on both side walls of the metal wire 20a, a step coverage characteristic of the second insulating layer is not excellent, and so voids are artificially formed within the second insulating layer 50 between the metal wires 20a.

As described above, air having a dielectric constant of 0 (zero) is contained in voids artificially formed in the second insulating layer 50 between the metal wires 20a. Accordingly, even though a insulating layer made of low dielectric material is not formed between the metal wires 20a, the second insulating layer 50 having the voids 60 formed therein lowers a dielectric ratio between the metal wires 20a so that it is possible to reduce the parasitic capacitance between the metal wires 20a to improve the resistance-capacitance (RC) delay characteristic caused by interference between the metal wires 20a.

After forming the second insulating layer 50, on the other hand, a chemical mechanical polishing (CMP) process can be further performed for planarizing the second insulating layer 50. As described above, since the second insulating layer 50 formed of any one of the PE-TEOS layer, the PE-UGS layer, and the PE-FSG layer has voids 60 formed therein, the second insulating layer achieves a low dielectric ratio and has a high mechanical strength so that the second insulating layer can withstand mechanical effects during a subsequent chemical mechanical polishing (CMP) process to enhance reliability of the semiconductor device.

In addition, when desired to develop a substance having a low dielectric ratio for satisfying a characteristic of the device, the low dielectric ratio is realized and the electrical characteristic and the mechanical strength of the device can be maintained by conventional material and equipment, and manufacturing cost is thereby minimized.

The method of forming the metal wire of the semiconductor device according to one embodiment of the invention is applicable to various methods for manufacturing DRAM, SRAM, and flash memory devices as well as to methods for manufacturing other devices embodying micro conductive circuitry wires.

The invention as described above has the advantages as follows.

First, the spacers preferably formed of the O₃-TEOS layer are formed on both side walls of the metal wire to reduce gaps between the metal wires before forming an insulating layer. Accordingly, voids are artificially formed in the insulating layer formed between the metal wires in a subsequent process to lower the dielectric ratio of the insulating layer between the metal wires. Due to the low dielectric ratio of the insulating layer between the metal wires, the parasitic capacitance between the metal wires can be reduced to improve the resistance-capacitance (RC) delay characteristic caused by the interference between the metal wires.

Second, since the dense, preferably O₃-TEOS layers formed through the SACVD method act as the spacers, it is possible to reduce a leakage current through the side walls of the metal wires.

Third, the insulating layer filling a gap between the metal wires and having voids formed therein are formed with material having a mechanical strength higher than that of low dielectric material so that the insulating layer can withstand mechanical effects during a subsequent CMP process to enhance the reliability of the device.

Fourth, in the invention, the low dielectric ratio between the metal wires can be achieved and an electrical characteristic and a mechanical strength of the metal wire can be maintained by use of the conventional substances and equipment, so manufacturing costs may be minimized.

Although the invention has been described with reference to a number of illustrative embodiments thereof, numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings, and the appended claims. In addition to variations and modifications in the component parts and/or arrangements, alternative uses may also be apparent to those skilled in the art.

What is claimed is:

1. A method of fabricating a semiconductor device, comprising:
forming a metal layer on a semiconductor substrate;
patterning the metal layer to form a plurality of metal wires, said metal wires each having two side surfaces;
forming spacers on both side surfaces of each of the metal wires; and
forming an insulating layer between the spacers of adjacent metal wires, the insulating layer having voids formed therein and comprising a material having a dielectric constant which differs from that of the spacers.

2. The method of fabricating a semiconductor device of claim 1, wherein the spacers comprise O₃-TEOS (Tetra Ethyl Ortho Silicate) layers.

3. The method of fabricating a semiconductor device of claim 2, comprising forming the O₃-TEOS layers by a sub-atmospheric chemical vapor deposition (SACVD) method.

4. The method of fabricating a semiconductor device of claim 3, comprising performing the sub-atmospheric chemical vapor deposition (SACVD) method in a chamber at a temperature of 500° C. to 550° C.

5. The method of fabricating a semiconductor device of claim 1, wherein the spacers have a thickness of 100 Å to 1,500 Å.

6. The method of fabricating a semiconductor device of claim 1, wherein forming the spacers comprises:
forming a O₃-TEOS layer on the semiconductor substrate along a plurality of metal wires; and
etching the O₃-TEOS layer to form spacers on both side walls of each of the metal wires.

7. The method of fabricating a semiconductor device of claim 1, wherein the insulating layer comprises material having a dielectric constant lower than that of the spacer.

8. The method of fabricating a semiconductor device of claim 1, comprising forming the insulating layer by a plasma enhanced chemical vapor deposition (PECVD) method.

9. The method of fabricating a semiconductor device of claim 1, wherein the insulating layer comprises one selected from the group consisting of PE-TEOS (Plasma Enhanced-Tetra Ethyl Ortho Silicate) layers, PE-USG (Plasma Enhanced-Undoped Silicate Glass) layers, and PE-FSG ((Plasma Enhanced-Fluoro Silicate Glass) layers.

10. The method of fabricating a semiconductor device of claim 1, wherein the insulating layer has a thickness of 1,000 Å to 13,000 Å.

11. A method of fabricating a semiconductor device, comprising:
forming a metal layer on a semiconductor substrate;
patterning the metal layer to form a plurality of metal wires, said metal wires each having two side surfaces;
forming spacers on both side surfaces of each of the metal wires; and
forming an insulating layer between the spacers of adjacent metal wires, the insulating layer having voids formed therein and comprising of material having a mechanical strength higher than that of a low dielectric material.

12. The method of fabricating a semiconductor device of claim 11, wherein the spacer comprises a O₃-TEOS (Tetra Ethyl Ortho Silicate) layer.

13. The method of fabricating a semiconductor device of claim 12, comprising forming the O₃-TEOS layer by a sub-atmospheric chemical vapor deposition (SACVD) method.

14. The method of fabricating a semiconductor device of claim 13, comprising performing the sub-atmospheric chemical vapor deposition (SACVD) method in a chamber at a temperature of 500° C. to 550° C.

15. The method of fabricating a semiconductor device of claim 11, wherein forming the spacer comprises:
forming a O₃-TEOS layer on the semiconductor substrate along a plurality of metal wires; and
etching the O₃-TEOS layer to form spacers on both side walls of each of the metal wires.

16. The method of fabricating a semiconductor device of claim 11, comprising forming the insulating layer through a plasma enhanced chemical vapor deposition (PECVD) method.

17. The method of fabricating a semiconductor device of claim 11, the insulating layer comprises one selected from the group consisting of PE-TEOS (Plasma Enhanced-Tetra Ethyl Ortho Silicate) layers, PE-USG (Plasma Enhanced-Undoped Silicate Glass) layers, and PE-FSG ((Plasma Enhanced-Fluoro Silicate Glass) layers.

18. The method of fabricating a semiconductor device of claim 11, wherein the insulating layer has a thickness of 1,000 Å to 13,000 Å.

19. A semiconductor device, comprising;
a plurality of metal wires formed on a semiconductor substrate, said metal wires each having two side walls;
spacers formed on both side walls of each of the metal wires; and
an insulating layer containing voids formed therein, the insulating layer being formed between the spacers of adjacent metal wires.

20. The semiconductor device of claim 19, wherein the spacer comprises a O₃-TEOS (Tetra Ethyl Ortho Silicate) layer.

21. The semiconductor device of claim 19, wherein the spacer has a thickness of 100 Å to 1,500 Å.

22. The semiconductor device of claim 19, wherein the insulating layer comprises material having a dielectric constant lower than that of the spacer.

23. The semiconductor device of claim 19, wherein the insulating layer comprises material having a mechanical strength higher than that of a low dielectric material.

24. The semiconductor device of claim 23, wherein the insulating layer comprises one selected from the group consisting of PE-TEOS (Plasma Enhanced-Tetra Ethyl Ortho Silicate) layers, PE-USG (Plasma Enhanced-Undoped Silicate Glass) layers, and PE-FSG (Plasma Enhanced-Fluoro Silicate Glass) layers.

25. The semiconductor device of claim 19, wherein the insulating layer has a thickness of 1,000 Å to 13,000 Å.
